(19) United States
(12) Patent Application Publication
(10) Pub. No.: US 2026/0271683 A1
(43) Pub. Date: Sep. 10, 2026

(54) FILM FORMING METHOD AND ARTICLE MANUFACTURING METHOD

(71) Applicant: CANON KABUSHIKI KAISHA, Tokyo (JP)

(72) Inventors: YUTO ITO, Tokyo (JP); TOSHIKI ITO, Kanagawa (JP)

(21) Appl. No.: 19/043,959

(22) Filed: Feb. 3, 2025

(30) Foreign Application Priority Data
Feb. 7, 2024 (JP) 2024-017429

(51) Int. Cl. H10P 95/00; C09D 11/38; H10P 14/60; H10P 76/20

(52) U.S. Cl. CPC H10P 95/08; C09D 11/38; H10P 14/6346; H10P 14/6536; H10P 14/6686; H10P 76/2041

(57) ABSTRACT

The present invention provides a film forming method of forming a planarization film on a substrate using a superstrate having a flat surface, comprising: discretely arranging a curable composition (A) as a plurality of droplets on a substrate; waiting until the plurality of droplets arranged on the substrate in the arranging combine with each other on the substrate to form a liquid film; bringing the liquid film on the substrate and the flat surface of the superstrate into contact with each other after the waiting; heating and curing the liquid film after the bringing, thereby forming a cured film between the superstrate and the substrate; and releasing the superstrate from the cured film after the curing.

### BACKGROUND OF THE INVENTION

### Field of the Invention

The present invention relates to a film forming method and an article manufacturing method.

### Description of the Related Art

A photolithography step of fabricating a semiconductor device requires planarization of a substrate (that is, formation of a planarization film on a substrate). For example, in an extreme ultraviolet exposure technique (EUV) as a photolithography technique attracting attention in recent years, the depth of focus at which a projected image is formed decreases as miniaturization advances, so the unevenness on the surface of a substrate to which a curable composition is supplied must be decreased to a few tens nm or less. Flatness equivalent to that of EUV is required in an imprint technique as well, in order to improve the filling properties of a curable composition and the line width accuracy (see NPL 1). As a planarization technique, there is known a technique of obtaining a flat surface by discretely dropping, on an uneven substrate, droplets of a curable composition in an amount corresponding to the unevenness, and curing the curable composition in a state in which a mold having a flat surface is in contact with the curable composition (see PTLs 1 and 2). Note that the mold having a flat surface is sometimes called a superstrate.

The planarization film formed by the planarization technique is required not only to be flat but also to reduce mixing of foreign substances. For this reason, in the planarization technique, adhesion of foreign substances on the superstrate (flat surface) needs be close to zero. In the conventional planarization technique, generally, a photocurable composition is cured by irradiation of light (for example, UV light) (see PTLs 4 and 5), and a superstrate made of quartz glass capable of transmitting light is used. However, when the superstrate made of quartz glass is used, it is difficult to make foreign substances on the superstrate (flat surface) close to zero.

In addition, the planarization film formed by the planarization technique is sometimes required to have not only flatness but also a heat resistance of about 450° C. or more. However, if a photocurable composition is used, as in the conventional planarization technique, the limit of the heat resistance is 450° C., and it is difficult to form a planarization film having a higher heat resistance.

Furthermore, the planarization film formed by the planarization technique is sometimes required to be a permanent insulating film. However, for the photocurable composition used in the conventional planarization technique, satisfying insulating performance, mechanical strength, and resistance required from the permanent insulating film is difficult and is not implemented.

### CITATION LIST

### Patent Literature

PTL 1: Japanese Patent Laid-Open No. 2019-140394
PTL 2: US-2020-0286740
PTL 3: Japanese Patent Laid-Open No. 2009-503139
PTL 4: Japanese Patent Laid-Open No. 2022-27530
PTL 5: US-2023-0203210

### Non Patent Literature

NPL 1: Proc. SPIE 11324-11 (2020)
NPL 2: A. Oron, S. H. Davis, S. G. Bankoff, “Long-scale evolution of thin liquid films”, Review of Modern Physics 69 (1997) 931

### SUMMARY OF THE INVENTION

The present invention provides, for example, a new technique concerning a method of forming a planarization film on a substrate.

According to one aspect of the present invention, there is provided a film forming method of forming a planarization film on a substrate using a superstrate having a flat surface, comprising: discretely arranging a curable composition (A) as a plurality of droplets on a substrate; waiting until the plurality of droplets arranged on the substrate in the arranging combine with each other on the substrate to form a liquid film; bringing the liquid film on the substrate and the flat surface of the superstrate into contact with each other after the waiting; heating and curing the liquid film after the bringing, thereby forming a cured film between the superstrate and the substrate; and releasing the superstrate from the cured film after the curing, wherein the curable composition (A) arranged on the substrate in the arranging is a thermosetting curable composition having a characteristic of being cured by heating, and contains at least a solvent (d), wherein a viscosity of the curable composition (A) at 23° C. is not less than 2 mPa·s and not more than 60 mPa·s, wherein a content of the solvent (d) in the curable composition (A) is not less than 5 vol % and not more than 95 vol %, wherein a boiling point of the solvent (d) at normal pressure is less than 250° C., and wherein a mixture other than the solvent (d) in the curable composition (A) has a viscosity of not less than 30 mPa·s and not more than 10,000 mPa·s at 23° C.

Further features of the present invention will become apparent from the following description of exemplary embodiments with reference to the attached drawings.

### BRIEF DESCRIPTION OF THE DRAWINGS

FIG. 1 is a view for explaining a film forming method according to an embodiment of the present invention;

FIG. 2 is a view for explaining a flow behavior of droplets of a curable composition during a waiting step; and

FIG. 3 is a view showing comparison between a contact step in a conventional technique and a contact step in the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

### [Curable Composition (A1)]

A curable composition (A1) of the present invention is a thermosetting curable composition having a characteristic of being cured by heating, and can be a curable composition for inkjet. The curable composition (A1) according to an embodiment is a composition containing at least a component (a) as a polymerizable compound, a component (b) as a photopolymerization initiator, and a component (d) as a solvent. In the embodiment, the component (a) as a polymerizable compound preferably contains at least a polymerizable compound (a-1) containing one or more aromatic rings or aromatic heterocycles and one or more vinyl groups directly combining with the aromatic rings or aromatic heterocycles. The curable composition (A1) of the embodiment can further contain a nonpolymerizable compound (c).

### <Component (a): Polymerizable Compound>

The component (a) is a polymerizable compound containing one or more aromatic rings or aromatic heterocycles and a vinyl group directly combining with the aromatic rings or aromatic heterocycles. In this specification, the polymerizable compound is a compound that reacts with a polymerizing factor (for example, a radical or cation) generated from a photopolymerization initiator (the component (b)), and forms a film made of a polymer compound by a chain reaction (thermal polymerization reaction).

Examples of the polymerizable compound are a radical polymerizable compound and a cation polymerizable compound. The component (a) as a polymerizable compound can be formed by only one type of a polymerizable compound, and can also be formed by a plurality of types (two or more types) of polymerizable compounds. That is, the component (a) as a polymerizable compound may contain one or more types of polymerizable compounds. Also, the component (a) as a polymerizable compound may contain at least a polymer having a polymerizable functional group.

In the embodiment, the component (a) as a polymerizable compound preferably contains at least a polymerizable compound (a-1) containing one or more aromatic rings or aromatic heterocycles and one or more vinyl groups directly combining with the aromatic rings or aromatic heterocycles.

<Compound (a-1): Polymerizable Compound>

Practical examples of the compound (a-1) are as follows. However, the compound (a-1) is not limited to these examples.

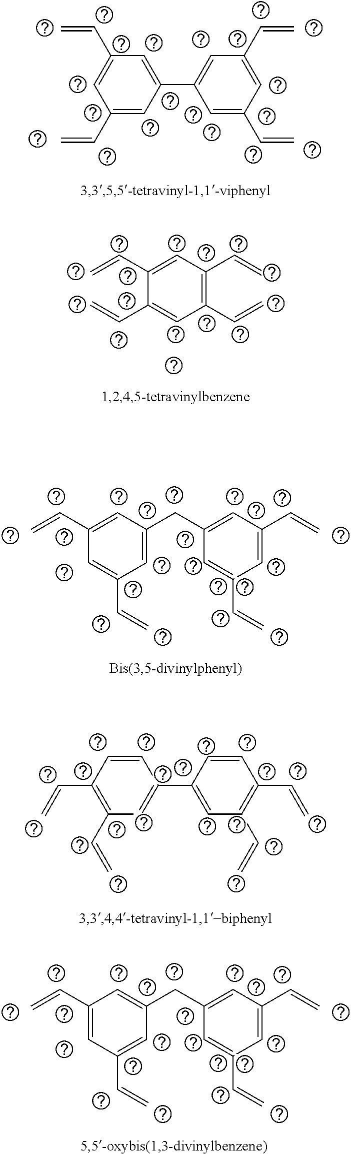

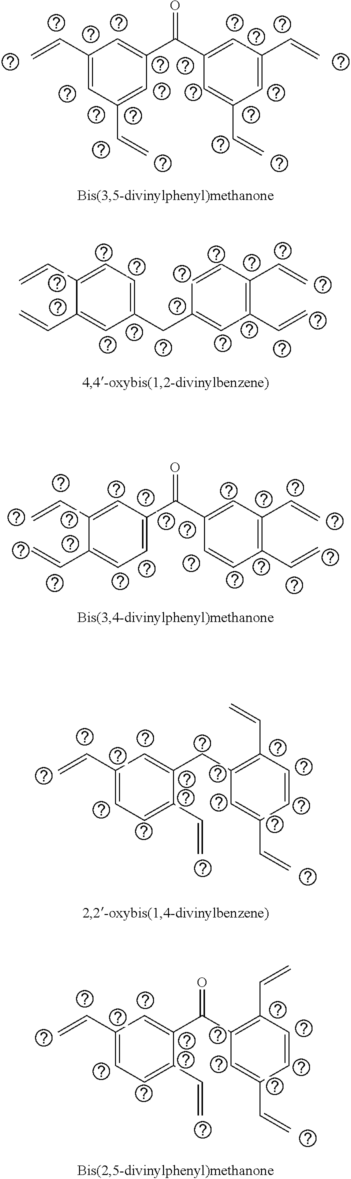

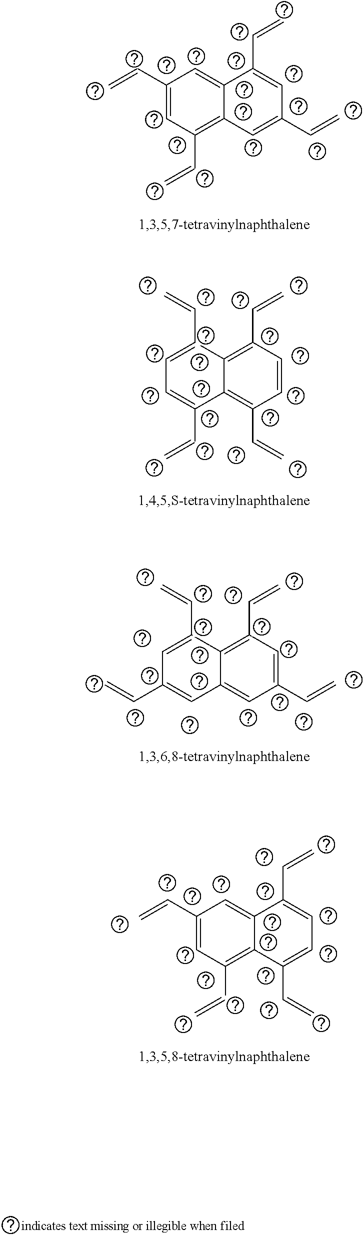

An example of the component (a) not corresponding to the compound (a-1) is a (meth)acrylic compound as a radical polymerizable compound.

The (meth)acrylic compound is a compound having one or more acryloyl groups or methacryloyl groups. Examples of a monofunctional (meth)acrylic compound having one acryloyl group or methacryloyl group are as follows, but the compound is not limited to these examples.

Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy(meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone(meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, and cyanobenzyl (meth)acrylate.

Examples of commercially available products of the above-described monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL); KAYARAD® TC110S, R-564, and R-128H (manufactured by NIPPON KAYAKU); NK Ester AMP-10G, AMP-20G, and A-LEN-10 (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); and ACMO, DMAA, and DMAPAA (manufactured by Kohjin).

Examples of a polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl) isocyanurate tri(meth)acrylate, tris(acryloyloxy) isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl) propane, PO-modified 2,2-bis(4-((meth)acryloxy)phenyl) propane, EO- and PO-modified 2,2-bis(4-((meth)acryloxy)phenyl) propane, o-, m-, or p-benzene di(meth)acrylate, and o-, m-, or p-xylylene di(meth)acrylate.

Examples of commercially available products of the above-described polyfunctional (meth)acrylic compounds are as follows, but the products are not limited to these examples.

Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); Ripoxy® VR-77, VR-60, and VR-90 (manufactured by Showa Highpolymer); and OGSOL EA-0200 and OGSOL EA-0300 (manufactured by Osaka Gas Chemicals).

Note that in the above-described compound group, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

The film forming method according to the embodiment of the present invention requires a few milliseconds to a few hundreds of seconds until droplets of the curable composition (A1) discretely arranged on a substrate combine with each other and form a practically continuous liquid film, so a waiting step (to be described later) is necessary. In this waiting step, the solvent (d) is volatilized, but the polymerizable compound (a) must not be volatilized. Hence, the boiling points of all the one or more types of polymerizable compounds contained in the polymerizable compound (a) are preferably 250° C. or more, more preferably 300° C. or more, and further preferably 350° C. or more at normal pressure. Also, to obtain a high dry etching resistance and a high heat resistance in the cured film of the curable composition (A1), the polymerizable compound (a) preferably contains at least a compound having a cyclic structure such as an aromatic structure, an aromatic heterocyclic structure, or an alicyclic structure.

The boiling point of the polymerizable compound (a) is almost correlated with the molecular weight. Therefore, the molecular weights of all the one or more types of polymerizable compounds contained in the polymerizable compound (a) are preferably 200 or more, more preferably 240 or more, and further preferably 250 or more. However, even when the molecular weight is 200 or less, the compound is preferably usable as the polymerizable compound (a) according to the embodiment of the present invention if the boiling point is 250° C. or more.

In addition, the vapor pressure at 80° C. of each of the one or more polymerizable compounds contained in the polymerizable compound (a) is preferably 0.001 mmHg or less. This is so because, although it is favorable to perform heating to accelerate volatilization of the solvent (d) (to be described later), it is necessary to suppress volatilization of the polymerizable compound (a) during heating.

Note that the boiling point and the vapor pressure of each organic compound at normal pressure can be calculated by, for example, Hansen Solubility Parameters in Practice (HSPiP) 5th Edition. 5.3.04.

<Ohnishi Parameter (OP) of Component (a)>

It is known that a dry etching rate V of an organic compound, a number N of all atoms in the organic compound, a number N_{C} of all carbon atoms in a composition, and a number N_{O} of all oxygen atoms in the composition have a relationship of equation (1) below (NPL 2).

$$V ∝ N / ( {N}_{C} - {N}_{o} ) \qquad ( 1 )$$

where N/(N_{C}−N_{O}) is also called “Ohnishi Parameter” (to be referred to as OP hereinafter). For example, PTL 3 describes a technique of obtaining a curable composition having a high dry etching resistance by using a polymerizable compound component having a small OP.

Equation (1) indicates that an organic compound having many oxygen atoms in a molecule or having few aromatic ring structures or alicyclic structures has a large OP and a high dry etching rate.

In the curable composition (A1) according to the embodiment of the present invention, the OP of the component (a) is preferably 1.80 or more and 2.70 or less, further preferably 2.00 or more and 2.60 or less, and particularly preferably 2.30 or more and 2.60 or less. When the OP of the component (a) is 2.70 or less, the cured film of the curable composition (A1) has a high dry etching resistance. Also, when the OP of the component (a) is 1.80 or more, the cured film of the curable composition (A1) can easily be removed when the underlayer is processed by using the cured film of the curable composition (A1). When the component (a) is formed by a plurality of types of polymerizable compounds a1, a₂, . . . , aₙ, the OP can be calculated as a weighted average value (molar fraction weighted average value) based on the molar fraction as indicated by equation (2) below:

$$OP = {\sum }_{i = n} {n}_{i} {OP}_{i} = {n}_{1} {OP}_{1} + {n}_{2} {OP}_{2} + … + {n}_{n} {OP}_{n} \qquad ( 2 )$$

<Compound (a-2): Polymerizable Compound Having Boiling Point of 250° C. or More>

The curable composition (A1) according to the embodiment of the present invention, which is a polymerizable compound (a), can contain a compound (a-2) which has two or more cyclic structures and in which at least one of them is an aromatic structure or an aromatic heterocyclic structure.

Examples of the cyclic structure are an aromatic structure, an aromatic heterocyclic structure, and an alicyclic structure.

The carbon number of the aromatic structure is preferably 6 to 22, more preferably 6 to 18, and further preferably 6 to 10. Practical examples of the aromatic ring are as follows.

A benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring.

Of the above-described aromatic rings, a benzene ring or a naphthalene ring is preferable, and a benzene ring is more preferable. The aromatic ring can have a structure in which a plurality of rings are connected. Examples are a biphenyl ring and a bisphenyl ring.

The carbon number of the aromatic heterocyclic structure is preferably 1 to 12, more preferably 1 to 6, and further preferably 1 to 5. Practical examples of the aromatic heterocycle are as follows.

A thiophene ring, a furan ring, a pyrolle ring, an imidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiine ring, and a phenoxazine ring.

The carbon number of the alicyclic structure is preferably 3 or more, more preferably 4 or more, and further preferably 6 or more. In addition, the carbon number of the alicyclic structure is preferably 22 or less, more preferably 18 or less, further preferably 6 or less, and still further preferably 5 or less. Practical examples are as follows.

A cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydro dicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring.

Practical examples of the compound (a-2) having a boiling point of 250° C. or more are as follows, but the compound is not limited to these examples.

3-phenoxybenzyl acrylate (mPhOBzA, OP=2.54, boiling point=367.4° C., 80° C. vapor pressure=0.0004 mmHg, molecular weight=254.3)

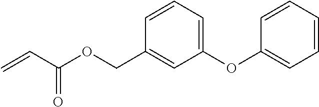 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

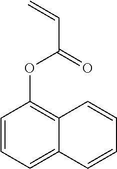

2-phenylphenoxyethyl acrylate (PhPhOEA, OP=2.57, boiling point=364.2° C., 80° C. vapor pressure=0.0006 mmHg, molecular weight=268.3)

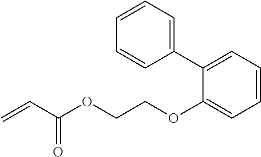 [SMILES: C=CC(=O)OCCOc1ccccc1-c1ccccc1]

1-naphthylmethyl acrylate (Na1MA, OP=2.33, boiling point=342.1° C., 80° C. vapor pressure=0.042 mmHg, molecular weight=212.2)

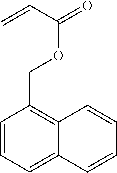 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

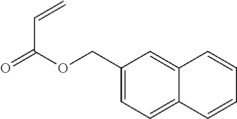 [SMILES: C=CC(=O)OCc1ccc2ccccc2c1]

DPhPA indicated by the formula below (OP=2.38, boiling point=354.5° C., 80° C. vapor pressure=0.0022 mmHg, molecular weight=266.3)

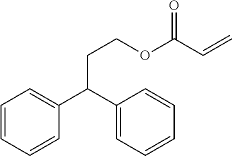 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

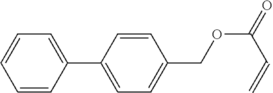 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

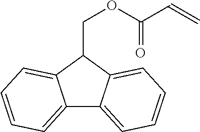 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

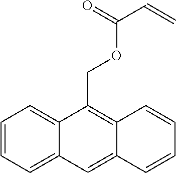 [SMILES: C=CC(=O)OCc1c2ccccc2cc2ccccc12]

DNaMA indicated by the formula below (OP=2.00, boiling point=489.4° C., 80° C. vapor pressure<0.0001 mmHg, molecular weight=338.4)

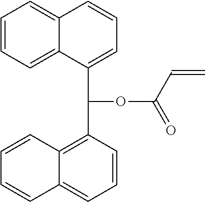 [SMILES: C=CC(=O)OC(c1cccc2ccccc12)c1cccc2ccccc12]

BPh44DA indicated by the formula below (OP=2.63, boiling point=444° C., 80° C. vapor pressure<0.0001 mmHg, molecular weight=322.3)

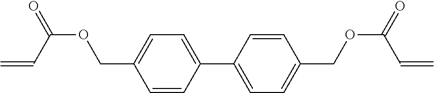 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure<0.0001 mmHg, molecular weight=322.3)

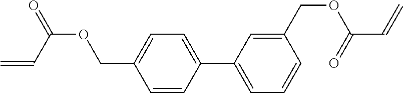 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure<0.0001 mmHg, molecular weight=322.3)

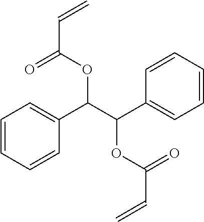 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure<0.0001 mmHg, molecular weight=364.4)

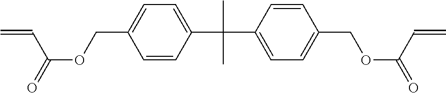 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure<0.0001 mmHg, molecular weight=296.3)

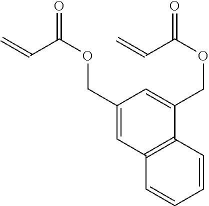 [SMILES: C=CC(=O)OCc1cc(COC(=O)C=C)c2ccccc2c1]

Formula (a-2-1) below (OP=2.40, boiling point=333.4° C., 80° C. vapor pressure=0.0181 mmHg, molecular weight=199.2)

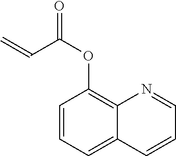

Formula (a-2-2) below (OP=2.40, boiling point=333.4° C., 80° C. vapor pressure=0.0181 mmHg, molecular weight=199.2)

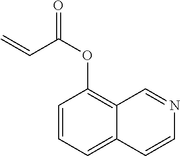

Formula (a-2-3) below (OP=1.86, boiling point=369.5° C., 80° C. vapor pressure=0.0053 mmHg, molecular weight=193.3)

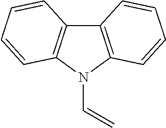

Formula (a-2-4) below (OP=2.85, boiling point=438.8° C., 80° C. vapor pressure<0.0001 mmHg, molecular weight=296.3)

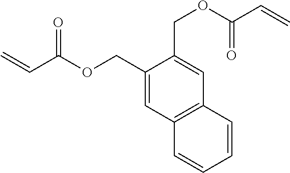 [SMILES: C=CC(=O)OCc1cc2ccccc2cc1COC(=O)C=C]

Formula (a-2-5) below (OP=2.71, boiling point=438.8° C., 80° C. vapor pressure<0.0001 mmHg, molecular weight=296.3)

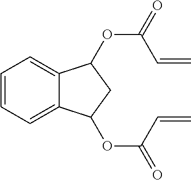 [SMILES: C=CC(=O)OC1CC(OC(=O)C=C)c2ccccc21]

Formula (a-2-6) below (OP=2.87, boiling point=421.0° C., 80° C. vapor pressure<0.0001 mmHg, molecular weight=338.4)

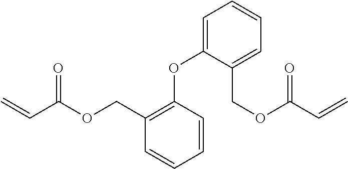 [SMILES: C=CC(=O)OCc1ccccc1Oc1ccccc1COC(=O)C=C]

Formula (a-2-7) below (OP=2.87, boiling point=465.2° C., 80° C. vapor pressure<0.0001 mmHg, molecular weight=338.4)

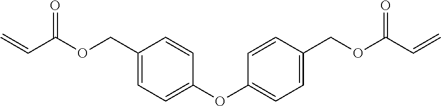 [SMILES: C=CC(=O)OCc1ccc(Oc2ccc(COC(=O)C=C)cc2)cc1]

Formula (a-2-8) below (OP=2.68, boiling point=465.7° C., 80° C. vapor pressure<0.0001 mmHg, molecular weight=364.4)

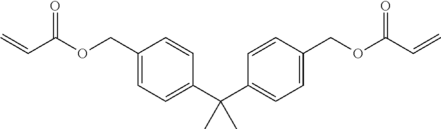 [SMILES: C=CC(=O)OCc1ccc(C(C)(C)c2ccc(COC(=O)C=C)cc2)cc1]

Formula (a-2-9) below (OP=2.50, boiling point=433.1° C., 80° C. vapor pressure<0.0001 mmHg, molecular weight=320.3)

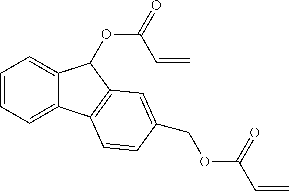 [SMILES: C=CC(=O)OCc1ccc2c(c1)C(OC(=O)C=C)c1ccccc1-2]

Formula (a-2-10) below (OP=2.64, boiling point=468.1° C., 80° C. vapor pressure<0.0001 mmHg, molecular weight=326.4)

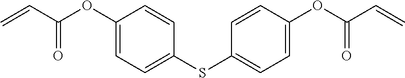 [SMILES: C=CC(=O)Oc1ccc(Sc2ccc(OC(=O)C=C)cc2)cc1]

Formula (a-2-11) below (OP=3.25, boiling point=553.4° C., 80° C. vapor pressure<0.0001 mmHg molecular weight=358.4)

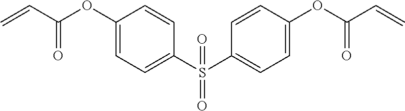 [SMILES: C=CC(=O)Oc1ccc(S(=O)(=O)c2ccc(OC(=O)C=C)cc2)cc1]

Formula (a-2-12) below (OP=2.63, boiling point=443.9° C., 80° C. vapor pressure<0.0001 mmHg, molecular weight=322.4)

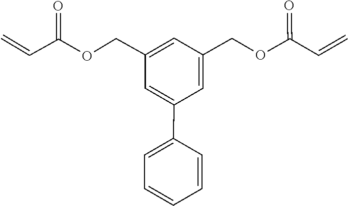 [SMILES: C=CC(=O)OCc1cc(COC(=O)C=C)cc(-c2ccccc2)c1]

Formula (a-2-13) below (OP=2.89, boiling point=509.3° C., 80° C. vapor pressure<0.0001 mmHg, molecular weight=406.4)

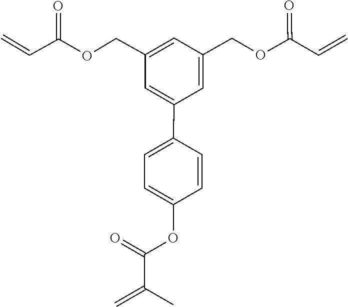 [SMILES: C=CC(=O)OCc1cc(COC(=O)C=C)cc(-c2ccc(OC(=O)C(=C)C)cc2)c1]

Formula (a-2-14) below (OP=2.63, boiling point=450.0° C., 80° C. vapor pressure<0.0001 mmHg, molecular weight=322.4)

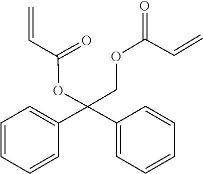 [SMILES: C=CC(=O)OCC(OC(=O)C=C)(c1ccccc1)c1ccccc1]

Formula (a-2-15) below (OP=3.00, boiling point=476.5° C., 80° C. vapor pressure<0.0001 mmHg, molecular weight=366.4)

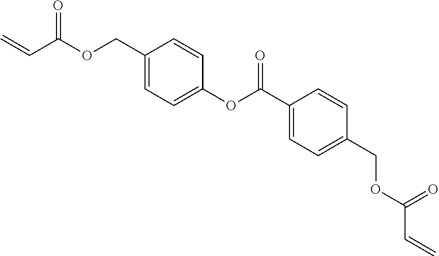 [SMILES: C=CC(=O)OCc1ccc(OC(=O)c2ccc(COC(=O)C=C)cc2)cc1]

Formula (a-2-16) below (OP=2.68, boiling point=447.4° C., 80° C. vapor pressure<0.0001 mmHg, molecular weight=364.4)

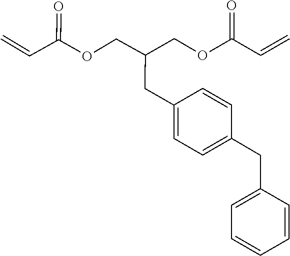 [SMILES: C=CC(=O)OCC(COC(=O)C=C)Cc1ccc(Cc2ccccc2)cc1]

Formula (a-2-17) below (OP=2.36, boiling point=543.8° C., 80° C. vapor pressure<0.0001 mmHg, molecular weight=398.5)

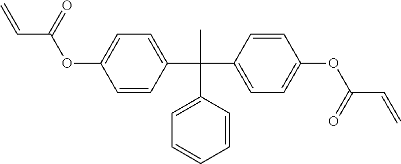 [SMILES: C=CC(=O)Oc1ccc(C(C)(c2ccccc2)c2ccc(OC(=O)C=C)cc2)cc1]

Formula (a-2-18) below (OP=3.27, boiling point=526.9° C., 80° C. vapor pressure<0.0001 mmHg, molecular weight=396.4)

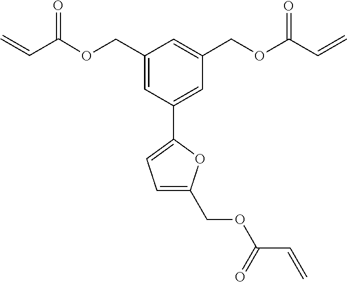 [SMILES: C=CC(=O)OCc1cc(COC(=O)C=C)cc(-c2ccc(COC(=O)C=C)o2)c1]

Formula (a-2-19) below (OP=2.71, boiling point=333.7° C., 80° C. vapor pressure=0.0302 mmHg, molecular weight=244.3)

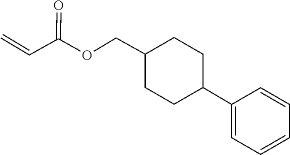 [SMILES: C=CC(=O)OCC1CCC(c2ccccc2)CC1]

Formula (a-2-20) below (OP=2.73, boiling point=333.7° C., 80° C. vapor pressure=0.0134 mmHg, molecular weight=258.3)

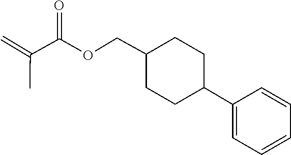 [SMILES: C=C(C)C(=O)OCC1CCC(c2ccccc2)CC1]

Formula (a-2-21) below (OP=2.71, boiling point=319.2° C., 80° C. vapor pressure=0.0566 mmHg, molecular weight=262.3)

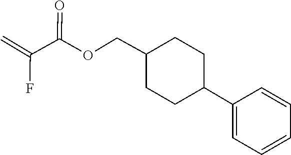 [SMILES: C=C(F)C(=O)OCC1CCC(c2ccccc2)CC1]

Formula (a-2-22) below (OP=2.71, boiling point=336.9° C., 80° C. vapor pressure=0.0055 mmHg, molecular weight=244.3)

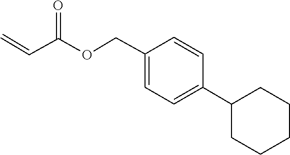 [SMILES: C=CC(=O)OCc1ccc(C2CCCCC2)cc1]

Formula (a-2-23) below (OP=3.00, boiling point=370.9° C., 80° C. vapor pressure=0.0021 mmHg, molecular weight=274.4)

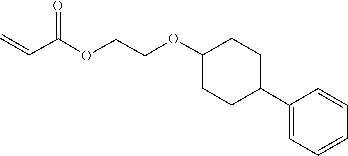 [SMILES: C=CC(=O)OCCOC1CCC(c2ccccc2)CC1]

Formula (a-2-24) below (OP=3.00, boiling point=376.4° C., 80° C. vapor pressure=0.0005 mmHg, molecular weight=274.4)

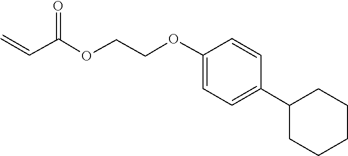 [SMILES: C=CC(=O)OCCOc1ccc(C2CCCCC2)cc1]

Formula (a-2-25) below (OP=3.00, boiling point=379.4° C., 80° C. vapor pressure=0.0002 mmHg, molecular weight=288.4)

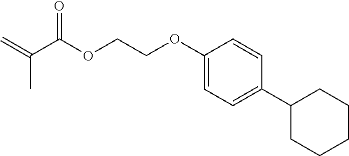 [SMILES: C=C(C)C(=O)OCCOc1ccc(C2CCCCC2)cc1]

Formula (a-2-26) below (OP=2.33, boiling point=360.8° C., 80° C. vapor pressure=0.0006 mmHg, molecular weight=252.3)

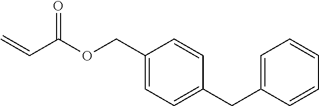 [SMILES: C=CC(=O)OCc1ccc(Cc2ccccc2)cc1]

Formula (a-2-27) below (OP=2.54, boiling point=371.5° C., 80° C. vapor pressure=0.0003 mmHg, molecular weight=254.3)

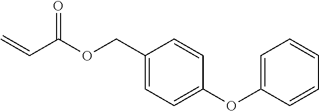 [SMILES: C=CC(=O)OCc1ccc(Oc2ccccc2)cc1]

Formula (a-2-28) below (OP=2.57, boiling point=381.2° C., 80° C. vapor pressure=0.0001 mmHg, molecular weight=268.3)

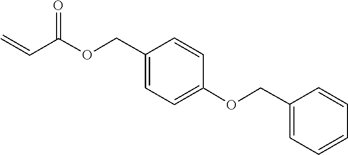 [SMILES: C=CC(=O)OCc1ccc(OCc2ccccc2)cc1]

Formula (a-2-29) below (OP=2.57, boiling point=381.8° C., 80° C. vapor pressure=0.0004 mmHg, molecular weight=268.3)

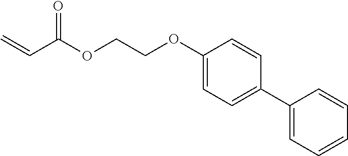 [SMILES: C=CC(=O)OCCOc1ccc(-c2ccccc2)cc1]

Formula (a-2-30) below (OP=2.50, boiling point=487.4° C., 80° C. vapor pressure<0.0001 mmHg, molecular weight=374.4)

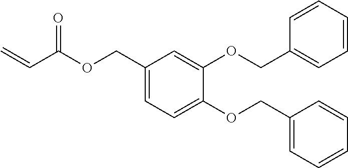 [SMILES: C=CC(=O)OCc1ccc(OCc2ccccc2)c(OCc2ccccc2)c1]

Formula (a-2-31) below (OP=2.67, boiling point=417.2° C., 80° C. vapor pressure<0.0001 mmHg, molecular weight=268.3)

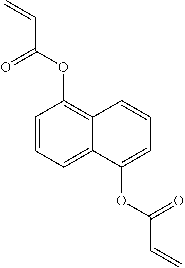 [SMILES: C=CC(=O)Oc1cccc2c(OC(=O)C=C)cccc12]

Formula (a-2-32) below (OP=2.67, boiling point=417.2° C., 80° C. vapor pressure<0.0001 mmHg, molecular weight=268.3)

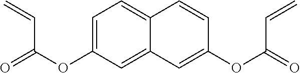 [SMILES: C=CC(=O)Oc1ccc2ccc(OC(=O)C=C)cc2c1]

Formula (a-2-33) below (OP=2.67, boiling point=417.2° C., 80° C. vapor pressure<0.0001 mmHg, molecular weight=268.3)

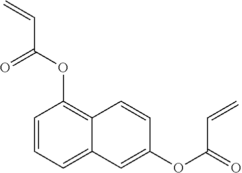 [SMILES: C=CC(=O)Oc1ccc2c(OC(=O)C=C)cccc2c1]

Formula (a-2-34) below (OP=2.67, boiling point=417.2° C., 80° C. vapor pressure<0.0001 mmHg, molecular weight=268.3)

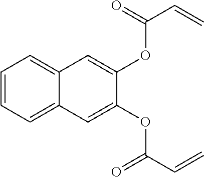 [SMILES: C=CC(=O)Oc1cc2ccccc2cc1OC(=O)C=C]

Formula (a-2-35) below (OP=2.71, boiling point=438.8° C., 80° C. vapor pressure<0.0001 mmHg, molecular weight=296.3)

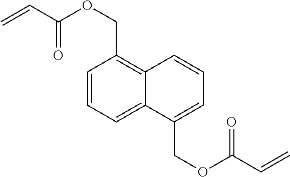 [SMILES: C=CC(=O)OCc1cccc2c(COC(=O)C=C)cccc12]

The blending ratio of the component (a) in the curable composition (A1) is preferably 40 wt % or more and 99 wt % or less with respect to the synthesis of a component (b) (to be described later) and a component (c) (to be described later), that is, the total mass of all the components except the solvent (d). The blending ratio of the component (a) in the curable composition (A1) is more preferably 50 wt % or more and 95 wt % or less, and further preferably 60 wt % or more and 90 wt % or less with respect to the total mass of all the components except the solvent (d). When the blending ratio of the component (a) is 40 wt % or more, the mechanical strength of the cured film of the curable composition (A1) increases. Also, when the blending ratio of the component (a) is 99 wt % or less, it is possible to increase the blending ratios of the components (b) and (c), and obtain characteristics such as a high thermal polymerization rate. Note that all the components except the solvent (d) in the curable composition (A1) may be understood as a mixture (composition (A1′)) except the solvent (d) of the curable composition (A1).

### <Component (b): Polymerization Initiator>

The polymerization initiator as the component (b) according to the embodiment of the present invention means, for example, a thermal radical generator or thermal acid generator, which generates a radical or cation as a polymerization factor by heat.

Examples of the thermal radical generator are an organic peroxide and an azo compound. Examples of the organic peroxide are peroxyesters such as t-hexylperoxyisopropyl monocarbonate, t-hexylperoxy-2-ethylhexanoate, t-butylperoxy-3,5,5-trimethylhexanoate, and t-butylperoxyisopropyl carbonates, peroxyketals such as 1,1-bis(t-hexylperoxy) 3,3,5-trimethylcyclohexane, and diacyl peroxides such as lauroyl peroxide, but the organic peroxides are not limited to these. Examples of the azo compound are azonitriles such as 2,2′-azobisisobutyronitrile, 2,2′-azobis(2-methylbutyronitrile), and 1,1′-azobis(cyclohexane-1-carbonitrile), but the azo compounds are not limited to these.

Examples of the thermal acid generator are an onium salt compound and an N-sulfonyloxyimide compound.

Examples of the onium salt compound are sulfonium salt, tetrahydrothiophenium salt, iodonium salt, and ammonium salt.

Examples of the sulfonium salt are triphenylsulfonium trifluoromethanesulfonate, triphenylsulfonium nonafluoro-n-butanesulfonate, triphenylsulfonium 2-bicyclo[2.2.1]hept-2-yl-1, 1,2,2-tetrafluoroethanesulfonate, 4-cyclohexylphenyl diphenylsulfonium trifluoromethanesulfonate.

Examples of the tetrahydrothiophenium salt are 1-(4-n-butoxynaphthalene-1-yl)tetrahydrothiophenium trifluoromethane sulfonate, 1-(4-n-butoxynaphthalene-1-yl)tetrahydrothiophenium nonafluoro-n-butane sulfonate, and 1-(4-n-butoxynaphthalene-1-yl)tetrahydrothiophenium 2-bicylo[2,2,1]hept-2-yl-1,1,2,2-tetrafluoroethane sulfonate.

Examples of the iodonium salt are diphenyliodonium trifluoromethane sulfonate, diphenyliodonium nonafluoro-n-butane sulfonate, bis(4-t-butylphenyl) iodonium nonafluoro-n-butane sulfonate, and bis(4-t-butylphenyl) iodonium 2-bicyclo[2,2,1]hept-2-yl-1,1,2,2-tetrafluoroethane sulfonate.

Examples of the ammonium salt are triethylammonium trifluoromethane sulfonate and triethylammonium nonafluoro-n-butane sulfonate.

Examples of the N-sulfonyloxyimide compound are N-(trifluoromethanesulfonyloxy)bicyclo[2,2,1]hept-5-ene-2,3-dicarboxyimide, N-(nonafluoro-n-butanesulfonyloxy)bicylo[2,2,1]hept-5-ene-2,3-dicarboxyimide, and N-(2-bicyclo[2,2,1]hept-2-yl-1,1,2,2-tetrafluoroethanesulfonyloxy)bicyclo[2,2,1]hept-5-ene-2,3-dicarboxyimide.

In these, as the thermal acid generator, the onium salt compound is favorable, and the iodonium salt and the ammonium salt are more favorable. As the thermal acid generator, bis(4-t-butylphenyl) iodonium nonafluoro-n-butane sulfonate and triethylammonium nonafluoro-n-butane sulfonate are further favorable.

The blending ratio of the component (b) in the curable composition (A1) is preferably 0.1 wt % or more and 50 wt % or less with respect to the sum of the component (a), the component (b), and a component (c) (to be described later), that is, the total mass of all the components except for the solvent (d). Also, the blending ratio of the component (b) in the curable composition (A1) is more preferably 0.1 wt % or more and 20 wt % or less, and further preferably 1 wt % or more and 20 wt % or less with respect to the total mass of all the components except for the solvent (d). When the blending ratio of the component (b) is set at 0.1 wt % or more, the curing rate of the composition increases, so the reaction efficiency can be improved. Also, when the blending ratio of the component (b) is set at 50 wt % or less, a cured film having mechanical strength to some extent can be obtained. Note that all the components except the solvent (d) in the curable composition (A1) may be understood as a mixture (composition (A1′)) except the solvent (d) of the curable composition (A1).

### <Component (c): Nonpolymerizable Compound>

In addition to the components (a) and (b) described above, the curable composition (A1) according to the embodiment of the present invention can further contain a nonpolymerizable compound as the component (c) within a range that does not impair the effect of this embodiment. Examples of the nonpolymerizable compound are an internal mold release agent, an antioxidant, a polymer component, and other additives. The component (c) can contain a plurality of types of the above-described compounds.

An internal mold release agent can be added to the curable composition (A1) for the purpose of reducing the interface bonding force between a superstrate (mold) and the curable composition (A1), that is, reducing the mold release force in a mold release step (to be described later). In the embodiment, “internal” means that the mold release agent is added to the curable composition (A1) in advance before an arranging step of the curable composition (A1). As the internal mold release agent, it is possible to use a surfactant such as a silicon-based surfactant, a fluorine-based surfactant, or a hydrocarbon-based surfactant. In the embodiment, however, the addition amount of the fluorine-based surfactant is limited as will be described later. Note that the internal mold release agent according to the embodiment is not polymerizable. It is possible to use one type of an internal mold release agent alone, or to use two or more types of internal mold release agents by mixing them.

The fluorine-based surfactant includes the following.

A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H,1H,2H,2H-perfluorooctylether.

It is also possible to use a commercially available product as the fluorine-based surfactant. Examples of the commercially available product of the fluorine-based surfactant are as follows.

MEGAFACE® F-444, TF-2066, TF-2067, and TF-2068, and DEO-15 (abbreviation) (manufactured by DIC); Fluorad FC-430 and FC-431 (manufactured by Sumitomo 3M); Surflon® S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE® DS-401, DS-403, and DS-451 (manufactured by DAIKIN); and FUTAGENT® 250, 251, 222F, and 208G (manufactured by NEOS).

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows.

A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of polyalkylene oxide are as follows.

Polyethylene glycol, polypropylene glycol, their mono or dimethyl ether, mono or dioctyl ether, mono or dinonyl ether, mono or didecyl ether, monoadipate ester, monooleate ester, monostearate ester, and monosuccinate ester.

A commercially available product can also be used as the alkyl alcohol polyalkylene oxide adduct. Examples of the commercially available product of the alkyl alcohol polyalkylene oxide adduct are as follows.

Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

The fluorine-based surfactant shows an excellent mold release force reducing effect and hence is effective as an internal mold release agent. The blending ratio of the component (c) except for the fluorine-based surfactant in the curable composition (A1) is preferably 0 wt % or more and 50 wt % or less with respect to the sum of the components (a), (b), and (c), that is, the total mass of all the components except for the solvent (d). The blending ratio of the component (c) except for the fluorine-based surfactant in the curable composition (A1) is more preferably 0.1 wt % or more and 50 wt % or less, and further preferably 0.1 wt % or more and 20 wt % or less with respect to the total mass of all the components except for the solvent (d). When the blending ratio of the component (c) except for the fluorine-based surfactant is set at 50 wt % or less, a cured film having mechanical strength to some extent can be obtained.

### <Component (d): Solvent>

The curable composition (A1) of the present invention contains a solvent having a boiling point of 80° C. or more and less than 250° C. at normal pressure as the component (d). The component (d) is a solvent that dissolves the components (a), (b), and (c). Examples are an alcohol-based solvent, a ketone-based solvent, an ether-based solvent, and a nitrogen-containing solvent. As the component (d), it is possible to use one type of a component alone, or to use two or more types of components by combining them. The boiling point at normal pressure of the component (d) is 80° C. or more, preferably 140° C. or more, and particularly preferably 150° C. or more. The boiling point at normal pressure of the component (d) is less than 250° C., and preferably 200° C. or less. If the boiling point of the component (d) at normal pressure is less than 80° C., the volatilization rate in a waiting step (to be described later) is too high, so it is possible that the component (d) volatilizes before droplets of the curable composition (A1) combine with each other, so the droplets of the curable composition (A1) do not combine. Also, if the boiling point at normal pressure of the component (d) is 250° C. or more, it is possible that the volatilization of the component (d) is insufficient in the waiting step (to be described later), so the component (d) remains in the cured film of the curable composition (A1). Here, if the component (d) contains one or more types of solvents, the boiling point of each of the one or more types of solvents contained in the component (d) at normal pressure is preferably 80° C. or more and less than 250° C., and preferably 150° C. or more and less than 200° C.

Examples of the alcohol-based solvent are as follows.

Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.

Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows.

Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy) ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.

Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.

N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples are as follows.

Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate. Note that ethyl) isocyanurate di(meth)acrylate is also favorable.

In the embodiment, a favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-haptanone, γ-butyrolactone, and ethyl lactate.

In the embodiment, the component (d) may contain a polymerizable compound having a boiling point of 80° C. or more and less than 250° C. at normal pressure. For example, a polymerizable compound having a boiling point of 80° C. or more and less than 250° C. at normal pressure is also usable as the component (d). Examples of the polymerizable compound having a boiling point of 80° C. or more and less than 250° C. at normal pressure are as follows.

Cyclohexyl acrylate (198° C.), benzyl acrylate (229° C.), isobornyl acrylate (245° C.), tetrahydrofurfuryl acrylate (202° C.), trimethylcyclohexyl acrylate (232° C.), isooctyl acrylate (217° C.), n-octyl acrylate (228° C.), ethoxyethoxyethyl acrylate (boiling point=230° C.), divinylbenzene (193° C.), 1,3-diisopropenylbenzene (218° C.), styrene (145° C.), and α-methylstyrene (165° C.).

In the embodiment, when the whole of the curable composition (A1) is 100 vol %, the content of the solvent (d) is 5 vol % or more and 95 vol % or less, preferably 5 vol % or more and 85 vol % or less, and further preferably 5 vol % or more and 80 vol % or less. If the content of the solvent (d) is smaller than 5 vol %, no thin film can be obtained after the solvent (d) volatilized even under the condition that a practically continuous liquid film can be obtained. On the other hand, if the content of the solvent (d) is larger than 95 vol %, no thick film can be obtained after the solvent (d) volatilized even when droplets are closely dropped by an inkjet method.

### <Glass Transition Temperature of Cured Curable Composition>

When the glass transition temperature is sufficiently higher than the temperature of mold release, a cured product (cured film) shows a strong glass state, that is, a high mechanical strength during mold release. For this reason, break hardly occurs due to impact of mold release. When performing the mold release step at room temperature, therefore, the glass transition temperature of the cured product is preferably 70° C. or more, more preferably 100° C. or more, and particularly preferably 150° C. or more.

As a method of measuring the glass transition temperature of the cured product, it can be measured by using differential scanning calorimetry (DSC) or a dynamic viscoelasticity apparatus. For example, when performing the measurement using DSC, a line obtained by extending the baseline of the DSC curve of a cured product on the low temperature side (a DSC curve portion in a temperature region where neither transition nor reaction occurs in a test piece) to the high temperature side and a tangent drawn at a point where the gradient of the curve of the stepwise change portion of glass transition is maximum are obtained. From the intersection between the line and the tangent, an extrapolated glass transition start temperature (Tig) is obtained, and this can be obtained as the glass transition temperature. An example of a major apparatus is STA-6000 (manufactured by Perkin Eimer). On the other hand, when performing measurement using a dynamic viscoelasticity apparatus, a temperature at which the loss sine (tan δ) of the cured product is maximum is defined as the glass transition temperature. An example of a major apparatus capable of measuring dynamic viscoelasticity is MCR301 (manufactured by Anton Paar).

### <Heat Resistance of Cured Curable Composition>

As a method of measuring the heat resistance of the cured curable composition (A1), it can be measured by using thermogravimetric analysis (TGA) or the like. When performing measurement by using TGA, for example, a cured curable composition is placed in a nitrogen atmosphere at a flow rate of 5 L/hr to 6 L/hr, and the thermogravimetry reduction rate is measured when the temperature is raised to n° C. at a heating rate of 20° C./min. This shows whether the product has a heat resistance to n° C. An example of a major apparatus is STA 1000 (manufactured by Linseis). As for the heat resistance of the cured product (cured film), when the temperature is increased from 200° C. at a heating speed of 20° C./min, a temperature at which a thermal weight decrease rate reaches 2% for the first time is preferably 250° C. or more, more preferably 350° C. or more, and particularly preferably 400° C. or more. That is, in a cured film obtained by a curing step, the weight decease when the temperature is increased from 200° C. to 250° C. at a heating speed of 20° C./min is preferably 2% or less.

Note that when using the curable composition (A1) according to the present invention in order to fabricate a semiconductor integrated circuit, it is favorable to avoid mixing of impurities (metal impurities) containing metal atoms in the curable composition (A1) as much as possible so as not to obstruct the operation of a product. The concentration of the metal impurities contained in the curable composition (A1) is preferably 10 ppm or less, and more preferably 100 ppb or less.

### [Curable Composition (A2)]

A curable composition (A2) according to the embodiment of the present invention can be a thermosetting curable composition having a characteristic of being cured by heating, and can be a curable composition for inkjet. The curable composition (A2) according to the embodiment is a composition containing at least a component (p) as a principal agent, a component (r) as a thermal acid generator, a component(s) as a crosslinking agent, and a component (d) as a solvent. The curable composition (A2) can further contain another arbitrary component (c) within a range that does not impair the effect of this embodiment. The components will be described below. Here, in the curable composition (A2), the content of carbon atoms in the components except for the solvent (d) (that is, a mixture of components except for the solvent (d)) is preferably 80 wt % or more.

### <Component (p): Principal Agent>

The component (p) is a principal agent. The component (p) is a compound containing an aromatic ring such as a benzene ring, a naphthalene ring, or an anthracene ring in a molecular weight of preferably 300 to 5,000, and particularly preferably 500 to 2,500. A molecular weight of 300 or more is advantageous in obtaining good deposition properties, and can suppress contamination of the manufacturing apparatus caused by an increase of sublimates at the time of curing. A molecular weight of 5,000 or less is advantageous in obtaining good embedding/planarization characteristics.

The component (p) can contain a branched or cyclic, saturated or unsaturated hydrocarbon group or heteroaromatic group. The component (p) can contain an ether group, a hydroxyl group, an ester group, a carbonyl group, an amino group, a halogen group, a sulfide group, a carboxyl group, a sulfo group, an amide group, an imide group, a cyano group, an aldehyde group, an imino group, a urea group, a carbamate group, a carbonate group, a nitro group, or a sulfonyl group.

Practical examples of the component (p) are as follows. Here, R indicates an alkyl group.

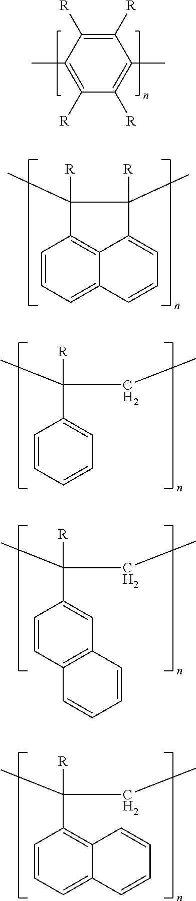

Other practical examples of the component (p) are novolak-based compounds such as phenol novolak, cresol novolak, and naphthol novolak, and substituted polystyrene compounds such as polyhydroxy styrene and polyhydroxy vinyl naphthalene. However, the component (p) is not limited to these. As the component (P), it is possible to use one type of a compound alone and two or more types of compounds by mixing them.

### <Component (d): Solvent>

The component (d) is not particularly limited as long as it can dissolve or disperse the component (p) and an arbitrary component to be contained as needed. Examples of the component (d) are an alcohol-based solvent, a ketone-based solvent, an ether-based solvent, an ester-based solvent, and a nitrogen-containing solvent. As the component (d), it is possible to use one type of a solvent alone and two or more types of solvents by combining them.

Examples of the alcohol-based solvent are as follows. Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows. Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows. Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy) ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows. Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate. Examples of the nitrogen-containing solvent are N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. From the viewpoint of good film formation properties, an ether-based solvent and an ester-based solvent each having a glycol structure are more favorable, propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate are further favorable, and propylene glycol monomethyl ether acetate is particularly favorable.

### <Component (r): Thermal Acid Generator>

The curable composition (A2) may contain a thermal acid generator as the component (r). The component (r) is a component that generates an acid by the action of heat or light and promotes the crosslinking reaction of the component (p) by the crosslinking agent (component(s)) to be described later. When the curable composition (A2) contains the component (r), the crosslinking reaction of the component (p) is promoted, and the hardness of a cured film to be formed can further be increased. As the component (r), it is possible to use one type of a component alone and two or more types of components by combining them. Examples of the component (r) are an onium salt compound and an N-sulfonyloxyimide compound.

Examples of the onium salt compound are tetrahydrothiophenium salt, iodonium salt, and ammonium salt.

Examples of the sulfonium salt are triphenylsulfonium trifluoromethane sulfonate, triphenylsulfonium nonafluoro-n-butane sulfonate, triphenylsulfonium 2-bicyclo[2,2,1]hept-2-yl-1,1,2,2-tetrafluoroethane sulfonate, and 4-cyclohexylphenyl diphenylfulfonium trifluoromethane sulfonate.

Examples of the tetrahydrothiophenium salt are 1-(4-n-butoxynaphthalene-1-yl)tetrahydrothiophenium trifluoromethane sulfonate, 1-(4-n-butoxynaphthalene-1-yl)tetrahydrothiophenium nonafluoro-n-butane sulfonate, and 1-(4-n-butoxynaphthalene-1-yl)tetrahydrothiophenium 2-bicylo[2,2,1]hept-2-yl-1,1,2,2-tetrafluoroethane sulfonate.

Examples of the iodonium salt are diphenyliodonium trifluoromethane sulfonate, diphenyliodonium nonafluoro-n-butane sulfonate, bis(4-t-butylphenyl) iodonium nonafluoro-n-butane sulfonate, and bis(4-t-butylphenyl) iodonium 2-bicyclo[2,2,1]hept-2-yl-1,1,2,2-tetrafluoroethane sulfonate.

Examples of the ammonium salt are triethylammonium trifluoromethane sulfonate and triethylammonium nonafluoro-n-butane sulfonate.

Examples of the N-sulfonyloxyimide compound are N-(trifluoromethanesulfonyloxy)bicyclo[2,2,1]hept-5-ene-2,3-dicarboxyimide, N-(nonafluoro-n-butanesulfonyloxy)bicylo[2,2,1]hept-5-ene-2,3-dicarboxyimide, and N-(2-bicyclo[2,2,1]hept-2-yl-1,1,2,2-tetrafluoroethanesulfonyloxy)bicyclo[2,2,1]hept-5-ene-2,3-dicarboxyimide.

Of these examples of the component (r), the onium salt compound is favorable, the iodonium salt and the ammonium salt are more favorable, and bis(4-t-butylphenyl) iodonium nonafluoro-n-butane sulfonate and triethylammonium nonafluoro-n-butane sulfonate are further favorable.

When the curable composition (A2) contains the component (r), the lower limit of the content of the component (r) is preferably 0.1 part by mass, more preferably 1 part by mass, and further preferably 3 parts by mass, with respect to 100 parts by mass of the component (p). The upper limit of the content of the component (r) is preferably 15 parts by mass, more preferably 12 parts by mass, and further preferably 10 parts by mass. When the content of the component (r) falls within the abovementioned range, the crosslinking reaction of the component (p) can be promoted more effectively.

### <Component(s): Crosslinking Agent>

The curable composition (A2) can also contain a crosslinking agent as the component(s). The component(s) is a component that forms a crosslinking bond between the compounds contained in the component (p) of the curable composition (A2), or forms a crosslinking structure by itself, by the action of heat or an acid. When the curable composition (A2) contains the component(s), the hardness of a cured film to be formed can be increased. As the component(s), it is possible to use one type of a component alone or two or more types of components by combining them.

Examples of the component(s) are a polyfunctional (meth)acrylate compound, an epoxy compound, a hydroxymethyl group-substituted phenol compound, an alkoxyalkyl group-containing phenol compound, and a compound having an alkoxyalkylated amino group.

Examples of the polyfunctional (meth)acrylate compound are trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl) isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, and bis(2-hydroxyethyl)isocyanulate di(meth)acrylate.

Examples of the epoxy compound are a novolak-type epoxy resin, a bisphenol-type epoxy resin, an alicyclic epoxy resin, and an aliphatic epoxy resin.

Examples of the hydroxymethyl group-substituted phenol compound are 2-hydroxymethyl-4,6-dimethylphenol, 1,3,5-trihydroxymethylbenzene, and 3,5-dihydroxymethyl-4-methoxytoluene[2,6-bis(hydroxymethyl)-p-cresol].

Examples of the alkoxyalkyl group-containing phenol compound are a methoxymethyl group-containing phenol compound and an ethoxymethyl group-containing phenol compound.

An example of the compound having an alkoxyalkylated amino group is a nitrogen-containing compound which has a plurality of active methylol groups in one molecule and in which at least one hydrogen atom of a hydroxyl group of the methylol group is substituted by an alkyl group such as a methyl group or a butyl group. Examples are (poly)methyloled melamine such as hexamethoxymethylated melamine, hexabutoxymethylated melamine, their alkoxy and/or hydroxy substitutes, and their partial self-condensates; (poly)methyloled glycoluril such as tetramethoxymethylated glycoluril, tetrabutoxymethylated glycoluril, their alkoxy and/or hydroxy substitutes, and their partial self-condensates; (poly)methyloled benzoguanamine such as tetramethoxymethylated benzoguanamine tetrabutoxymethylated benzoguanamine, their alkoxy and/or hydroxy substitutes, and their partial self-condensates; and (poly)methyloled urea such as dimethoxymethylated dimethoxyethylene urea, its alkoxy and/or hydroxy substitute, and their partial self-condensates. Note that the compound having an alkoxyalkylated amino group can be a mixture of a plurality of substitution compounds, and can also be a compound containing an oligomer component obtained by partial self-condensation.

When the curable composition (A2) contains the component(s), the lower limit of the content of the component(s) is preferably 0.1 part by mass, more preferably 0.5 parts by mass, further preferably 1 part by mass, and particularly preferably 3 parts by mass, with respect to 100 parts by mass of the component (p). The upper limit of the content of the component(s) is preferably 50 parts by mass, more preferably 40 parts by mass, further preferably 30 parts by mass, and particularly preferably 20 parts by mass. When the content of the component(s) falls within the abovementioned range, the crosslinking reaction of the component (p) can be caused more effectively.

### <Component (c): Another Arbitrary Component>

The curable composition (A2) may contain another arbitrary component (c). An example of the component (c) is a surfactant. When the curable composition (A2) contains a surfactant, the coating properties can be improved. Consequently, the coating surface uniformity of an underlayer film to be formed improves, and the occurrence of uneven coating can be suppressed. It is possible to use one type of a surfactant alone or two or more types of surfactants by combining them.

When the curable composition (A2) contains a surfactant, the lower limit of the content of the surfactant is preferably 0.01 part by mass, more preferably 0.05 parts by mass, and further preferably 0.1 part by mass, with respect to 100 parts by mass of the component (p). The upper limit of the content of the surfactant is preferably 10 parts by mass, more preferably 5 parts by mass, and further preferably 1 part by mass. When the content of the surfactant falls within the abovementioned range, the coating properties of the curable composition can further be improved.

### [Curable Composition (A3)]

A curable composition (A3) according to the embodiment of the present invention can be a thermosetting curable composition having a characteristic of being cured by heating, and can be a curable composition for inkjet. The curable composition (A3) according to the embodiment is a composition containing at least a siloxane component (q) and a component (d) as a solvent. The curable composition (A3) can further contain another arbitrary component (c) within a range that does not impair the effect of this embodiment. The components will be described below. Here, in the curable composition (A3), the content of silicon atoms in the components except for the solvent (d) (that is, a mixture of components except for the solvent (d)) is preferably 30 wt % or more.

“Siloxane component (q)” is a general term for polymer compounds having an Si—O bond (siloxane bond), and compounds indicated by general formulas such as chain siloxane H₃SiO(H₂SiO)ₙ—SiH₃ and cyclic siloxane (—H₂SiO—)ₙ are included.

Practical examples of the component (q) are as follows, but the component (q) is not limited to these. Here, R indicates an alkyl group or a hydroxy group.

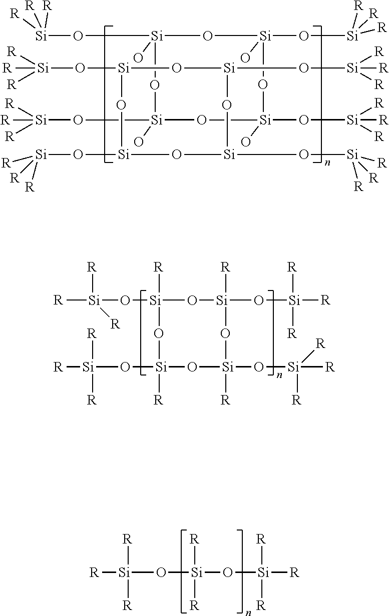

### <Component (d): Solvent>

The component (d) is not particularly limited as long as it can dissolve or disperse the component (q) and an arbitrary component to be contained as needed. Examples of the component (d) are an alcohol-based solvent, a ketone-based solvent, an ether-based solvent, an ester-based solvent, and a nitrogen-containing solvent. As the component (d), it is possible to use one type of a solvent alone and two or more types of solvents by combining them.

Examples of the alcohol-based solvent are as follows. Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows. Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows. Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy) ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows. Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate. Examples of the nitrogen-containing solvent are N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. From the viewpoint of good film formation properties, an ether-based solvent and an ester-based solvent each having a glycol structure are more favorable, propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate are further favorable, and propylene glycol monomethyl ether acetate is particularly favorable.

### <Component (c): Another Arbitrary Component>

The curable composition (A3) may contain another arbitrary component (c). An example of the component (c) is a surfactant. When the curable composition (A3) contains a surfactant, the coating properties can be improved. Consequently, the coating surface uniformity of an underlayer film to be formed improves, and the occurrence of uneven coating can be suppressed. It is possible to use one type of a surfactant alone or two or more types of surfactants by combining them.

When the curable composition (A3) contains a surfactant, the lower limit of the content of the surfactant is preferably 0.01 part by mass, more preferably 0.05 parts by mass, and further preferably 0.1 part by mass, with respect to 100 parts by mass of the component (q). The upper limit of the content of the surfactant is preferably 10 parts by mass, more preferably 5 parts by mass, and further preferably 1 part by mass. When the content of the surfactant falls within the abovementioned range, the coating properties of the curable composition can further be improved.

### [Curable Composition (A)]

Hereinafter, concerning features common to the above-described curable compositions (A1), (A2), and (A3), these will be described as a curable composition (A) altogether.

### <Temperature When Blending Curable Composition>

When preparing the curable composition (A) according to the embodiment of the present invention, the components are mixed and dissolved under a predetermined temperature condition. More specifically, the predetermined temperature condition is 0° C. or more and 100° C. or less.

### <Viscosity of Curable Component>

The curable composition (A) according to the embodiment of the present invention is a liquid. This is so because a plurality of droplets of the curable composition (A) are discretely dropped (arranged) on a substrate by an inkjet method in an arranging step (to be described later). At 23° C., the viscosity of the curable composition (A) according to the embodiment of the present invention is 2 mPa·s or more and 60 mPa·s or less, preferably 5 mPa·s or more and 30 mPa·s or less, and more preferably 5 mPa·s or more and 15 mPa·s or less. If the viscosity of the curable composition (A) is smaller than 2 mPa·s, the discharge property of droplets by an inkjet method becomes unstable. Also, if the viscosity of the curable composition (A) is larger than 60 mPa·s, it is impossible to form droplets having a volume of about 1.0 to 3.0 μL favorable in the embodiment.

The viscosity of components obtained by removing the solvent (d), that is, a mixture of components except for the solvent (d) of the curable composition (A) is 30 mPa·s or more and 10,000 mPa·s or less at 23° C. The viscosity of the mixture at 23° C. is preferably 90 mPa-s or more and 2,000 mPa·s or less, for example, 120 mPa·s or more and 1,000 mPa·s or less, and more preferably 150 mPa·s or more and 500 mPa·s or less. When the viscosity of the mixture at 23° C. is set to 1,000 mP·s or less, spreading and filling are rapidly completed when bringing the curable composition (A) into contact with a superstrate. Accordingly, the use of the curable composition (A) according to the embodiment of the present invention makes it possible to perform an imprinting process at high throughput, and suppress defects caused by insufficient filling. Also, when the viscosity of the mixture at 23° C. is set to 1 mPa·s or more, it is possible to prevent an unnecessary flow of droplets of the curable composition (A) after the solvent (d) volatilized. Furthermore, when bringing the curable composition (A) into contact with a superstrate, the curable composition (A) does not easily flow out from the end portions of the superstrate. Note that the mixture of components except for the solvent (d) of the curable composition (A) may be understood as components (a mixture or a composition) remaining after the solvent (d) is completely volatilized from the curable composition (A).

### <Surface Tension of Curable Composition>

As for the surface tension of the curable composition (A) according to the embodiment of the present invention, the surface tension of the mixture of components except for the solvent (d) of the curable composition (A) at 23° C. is preferably 5 mN/m or more and 70 mN/m or less. The surface tension of the mixture at 23° C. is more preferably 7 mN/m or more and 50 mN/m or less, and further preferably 10 mN/m or more and 40 mN/m or less. Note that when the surface tension of the mixture at 23° C. is high, for example, 5 mN/m or more, the capillarity strongly acts, so filling (spreading and filling) is complete within a short time period when the curable composition (A) and a superstrate are brought into contact with each other. Also, when the surface tension is 70 mN/m or less, a cured film obtained by curing the curable composition (A) has surface smoothness.

### <Contact Angle of Curable Composition>

As for the contact angle of the curable composition (A) according to the embodiment of the present invention, the contact angle of the mixture of components except for the solvent (d) of the curable composition (A) is preferably 0° or more and 90° or less with respect to both the surface of a substrate and the surface of a superstrate. The contact angle of the mixture is particularly preferably 0° or more and 10° or less. If the contact angle of the mixture is larger than 90°, the capillarity acts in a negative direction (a direction in which the contact interface between the superstrate and the curable composition (A) is shrunk) in a gap between the substrate and the superstrate, and this may make filling impossible. When the contact angle of the mixture is small, the capillarity strongly acts, and the filling rate increases.

### <Impurities Mixed in Curable Composition>

The curable composition (A) according to the embodiment of the present invention preferably contains impurities as little as possible. Note that impurities in the curable composition (A1) mean components other than the above-described components (a), (b), (c), and (d). Impurities in the curable composition (A2) mean components other than the above-described components (p), (s), (r), (d), and (c). Impurities in the curable composition (A3) mean components other than the above-described components (q), (d), and (c). Therefore, the curable composition (A) according to the embodiment of the present invention is favorably a composition obtained through a refining step. A refining step like this is preferably filtration using a filter.

As this filtration using a filter, it is favorable to mix, of the components described above, components other than the component (d) that is a solvent, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition (A) can be removed through the refining step as described above. Consequently, it is possible to prevent impurities mixed in the curable composition (A) from causing pattern defects by forming unexpected unevenness on a cured film obtained after the curable composition (A) is cured.

### [Substrate]

In this specification, a member on which droplets of the curable composition (A) are discretely dropped is explained as a substrate.

This substrate is a substrate to be processed, and a silicon wafer is normally used. The substrate can have a layer to be processed on the surface. On the substrate, another layer can also be formed below the layer to be processed. However, the substrate is not limited to a silicon wafer or a quartz substrate. The substrate can freely be selected from those known as semiconductor device substrates such as aluminum, a titanium-tungsten alloy, an aluminum-silicon alloy, an aluminum-copper-silicon alloy, silicon oxide, and silicon nitride. Note that the surface of the substrate or of the layer to be processed is preferably treated by a surface treatment such as a silane coupling treatment, a silazane treatment, or deposition of an organic thin film, thereby improving the adhesion to the curable composition (A).

### [Film Forming Method]

A film forming method according to the embodiment of the present invention will be described below. The film forming method is a method of forming a planarization film on a substrate using a mold and includes, for example, an arranging step, a waiting step, a contact step, a curing step, and a mold release step. The arranging step is a step of arranging the curable composition (A) as a plurality of droplets on a substrate. The waiting step is a step of waiting until the plurality of droplets of the curable composition (A) arranged on the substrate in the arranging step combine with each other to form a liquid film. The contact step is a step of bringing the liquid film of the curable composition (A) on the substrate and a mold into contact with each other. The curing step is a step of heating and curing the curable composition (A) in a state in which the liquid film of the curable composition (A) on the substrate and the mold are in contact, thereby forming a cured film of the curable composition (A) between the mold and the substrate. The mold release step is a step (separation step) of releasing the mold from the cured film of the curable composition (A). The waiting step is performed after the arranging step, the contact step is performed after the waiting step, the curing step is performed after the contact step, and the mold release step is performed after the curing step.

In the film forming method according to the embodiment of the present invention, as the substrate, a substrate having unevenness with a height difference of about 10 to 1,000 nm is used, and as the mold, a mold having a flat surface (to be sometimes referred to as a superstrate hereinafter) is used. The superstrate can be defined as a mold having a contact surface to be brought into contact with the curable composition (A) on the substrate, in which 90% or more (preferably, 95% or more) of the contact surface is a flat surface. In the film forming method according to the embodiment, a cured film having a surface conforming to the flat surface of the superstrate is formed on the substrate via the arranging step, the waiting step, the contact step, the curing step, and the mold release step described above. Here, in the arranging step, the droplets of the curable composition (A) are densely arranged in the recessed portions of the substrate, and the droplets of the curable composition (A) are coarsely arranged in the projecting portions of the substrate.

### <Arranging Step>

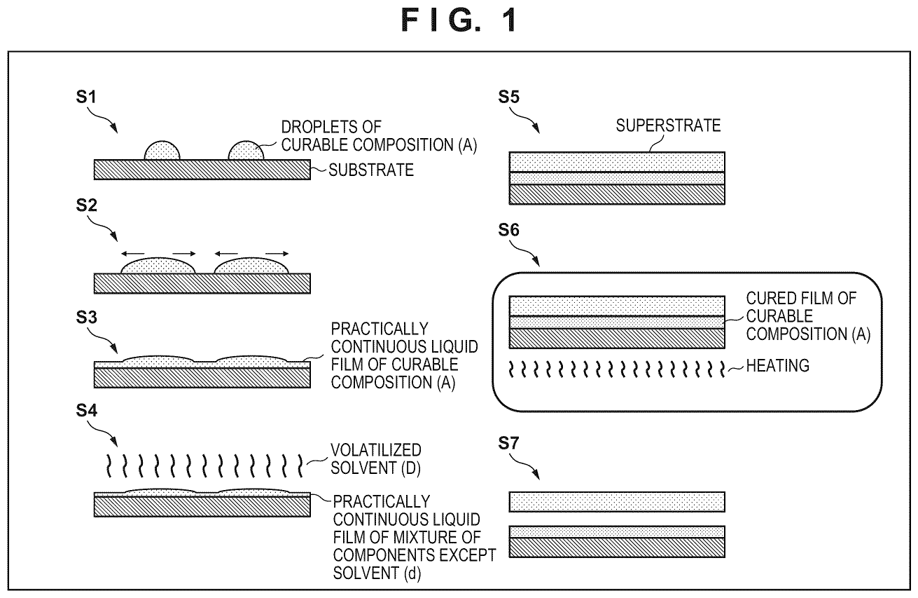

In the arranging step, as schematically shown in step 1 in FIG. 1, a plurality of droplets of the curable composition (A) are discretely arranged on a substrate. A substrate on which an underlayer is stacked can be used as the substrate. In addition, the adhesion of the surface of the substrate with respect to the curable composition (A) can be improved by a surface treatment such as a silane coupling treatment, a silazane treatment, or deposition of an organic thin film.

An inkjet method is particularly favorable as the arranging method of arranging the curable composition (A) as the plurality of droplets on the substrate. An index called an average residual liquid film thickness is defined in order to prescribe the volume of the curable composition (A) to be arranged on the substrate. The average residual liquid film thickness is a value obtained by dividing the volume of the curable composition (A) (more specifically, a mixture of components except the solvent (d)) to be arranged on the substrate in the arranging step by the area of a film formation region (the contact surface or the flat surface) of the superstrate. The volume of the curable composition (A) (more specifically, a mixture of components except the solvent (d)) is the sum total of the volumes of the individual droplets of the curable composition (A) after the solvent (d) volatilized. According to this definition, the average residual liquid film thickness can be prescribed regardless of the state of unevenness even when the substrate surface is uneven.

### <Waiting Step>

In the waiting step, as schematically shown in step 2 in FIG. 1, the droplets of the curable composition (A) spread on the substrate. Consequently, the whole region (film formation region) of the substrate where a planarization film is to be formed is covered with the curable composition (A), as schematically shown in step 3 in FIG. 1.

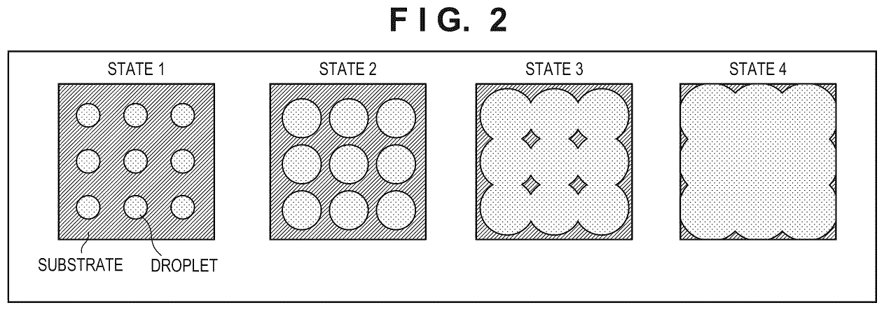

A flow behavior during the waiting step of the droplets of the curable composition (A) arranged on the substrate will be explained with reference to state 1 to state 4 in FIG. 2. The droplets of the curable composition (A) are discretely arranged on the substrate, as shown in step 1 in FIG. 2, and each droplet gradually spreads on the substrate, as shown in step 2 in FIG. 2. Then, the droplets of the curable composition (A) on the substrate begin combining with each other to form a liquid film, as shown in state 3 in FIG. 2, and a continuous liquid film is formed (the surface of the substrate is covered with the curable composition (A) and there is no more exposed surface), as shown in state 4 in FIG. 2. The state of the curable composition (A) as shown in state 4 in FIG. 2 is sometimes called “a practically continuous liquid film” hereinafter.

In addition, as schematically shown in step 4 in FIG. 1, the solvent (d) contained in the liquid film is volatilized in the waiting step. Assuming that the total weight of the components (mixture) except for the solvent (d) in the curable composition (A) forming the liquid film is 100 vol %, the residual amount (content) of the solvent (d) in the liquid film after the waiting step is preferably 10 vol % or less. That is, in the waiting step, the process waits until the residual amount (content) of the solvent (d) in the curable composition (A) forming the liquid film becomes 10 vol % or less with respect to the components (mixture) except for the solvent (d). If the residual amount of the solvent (d) is larger than 10 vol %, the mechanical properties of the cured film may deteriorate.

In the waiting step, it is possible to perform a baking step of heating the substrate and the curable composition (A), or ventilate the atmospheric gas around the substrate, for the purpose of accelerating the volatilization of the solvent (d). Heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

The waiting step is, for example, 0.1 to 600 sec, and preferably 10 to 300 sec. If the waiting step is shorter than 0.1 sec, the combination of the droplets of the curable composition (A) becomes insufficient, so no practically continuous liquid film is formed. If the waiting step exceeds 600 sec, the productivity decreases. To suppress the decrease in productivity, therefore, it is also possible to sequentially move substrates completely processed in the arranging step to the waiting step, perform the waiting step in parallel to a plurality of substrates, and sequentially move the substrates completely processed in the waiting step to the contact step. Note that in the related art, a few thousands of seconds to a few tens of thousands of seconds are theoretically required before a practically continuous liquid film is formed. In practice, however, no continuous liquid film can be formed because the spread of the droplets of the curable composition stagnates due to the influence of volatilization.

When the solvent (d) volatilizes in the waiting step, the practically continuous liquid film containing the components (mixture) other than the solvent (d) remains. The average residual liquid film thickness of the practically continuous liquid film after the solvent (d) volatilized (was removed) becomes smaller than the liquid film by the volatilized amount of the solvent (d). A state in which the film formation region of the substrate is covered with the practically continuous liquid film of the curable composition (A) from which the solvent (d) was removed is maintained in the entire region.

### <Contact Step>

In the contact step, as schematically shown in step 5 in FIG. 1, the superstrate is brought into contact with the practically continuous liquid film of the curable composition (A) from which the solvent (d) is removed. The contact step includes a step of changing a state in which the curable composition (A) and the superstrate are not in contact with each other to a state in which they are in contact with each other, and a step of maintaining the state in which they are in contact with each other. As a consequence, the liquid film of the curable composition (A) is planarized in accordance with the flatness of the contact surface (flat surface) of the superstrate.

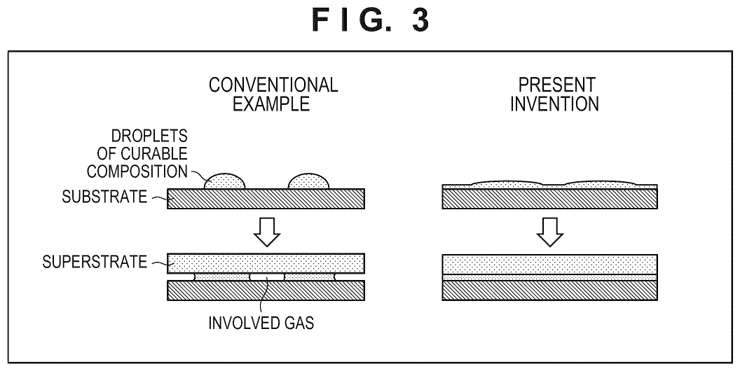

In the embodiment of the present invention, the curable composition (A) forms the practically continuous liquid film from which the solvent (d) is removed in the waiting step, so the volume of a gas involved between the superstrate and the substrate becomes small. Accordingly, spread of the curable composition (A) in the contact step is rapidly completed. FIG. 3 shows the comparison (difference) between the contact step in the related art disclosed in PTL 1 and the like and the contact step according to the embodiment of the present invention.

When spread and filling of the curable composition (A) are quickly completed in the contact step, it is possible to shorten the time (the time required for the contact step) for maintaining the state in which the superstrate is in contact with the curable composition (A). Since shortening the time required for the contact step leads to shortening the time required for formation of the planarization film, the productivity improves. The contact step is preferably 0.1 sec or more and 3 sec or less, and particularly preferably 0.1 sec or more and 1 sec or less. If the contact step is shorter than 0.1 sec, spread and filling become insufficient, so many defects called incomplete filling defects tend to occur.

The superstrate according to the embodiment of the present invention is preferably a silicon wafer or a quartz wafer, and particularly preferably a silicon wafer. As the silicon wafer, a commercially available silicon wafer having a size of 450 mmΦ, 300 mmΦ, 200 mmΦ, 150 mmΦ, 100 mmΦ, or 50 mmΦ can be used. Before the contact step, it is favorable to clean foreign substances existing on the contact surface of the superstrate and confirm, using an existing defect inspection apparatus or the like, that the number of foreign substances having a size of 50 nm or more and existing on the contact surface is 10 or less. When continuously using the superstrate by repeating the contact step, first, before the first contact step, the foreign substance cleaning and the foreign substance confirmation by the above-described method are performed. Every time the superstrate is continuously used a predetermined number of times (for example, 1,000 times), the foreign substance cleaning and the foreign substance confirmation by the above-described method before the contact step are preferably performed.

If the thermal expansion coefficient difference between the superstrate and the substrate is small, the strain of the cured film formed on the substrate can be made small. If a silicon wafer is used as the substrate, the thermal expansion coefficient of the substrate at 290 K to 310 K is preferably 1×10⁻⁶ K⁻¹ or more and 7×10⁻⁶ K⁻¹ or less. The thermal expansion coefficient is more preferably 2×10⁻⁶ K⁻¹ or more and 6×10⁻⁶ K⁻¹ or less, and further preferably 3×10⁻⁶ K⁻¹ or more and 5×10⁻⁶ K⁻¹ or less.

When the thickness difference between the superstrate and the substrate is made small, the strain of the cured film formed on the substrate can be made small. If a silicon wafer having a size of 300 mmΦ is used as the substrate, the thickness of the superstrate is preferably 550 μm or more and 1,000 μm or less, more preferably 650 μm or more and 900 μm or less, and further preferably 750 μm or more and 800 μm or less. If a silicon wafer having a size of 200 mmΦ is used as the substrate, the thickness of the superstrate is preferably 500 μm or more and 950 μm or less, more preferably 600 μm or more and 850 μm or less, and further preferably 700 μm or more and 750 μm or less.

A surface treatment can also be performed on the superstrate before performing the contact step, in order to improve the detachability of the superstrate with respect to the curable composition (A). An example of this surface treatment is to form a mold release agent layer by coating the surface of the superstrate with a mold release agent. Examples of the mold release agent to be applied on the surface of the superstrate are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition (A) when bringing the superstrate into contact with the curable composition (A) is not particularly limited, and is, for example, 0 MPa or more and 100 MPa or less. The pressure is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

The curing step is provided for the purpose of curing the curable composition (A) to such an extent that does not cause peeling or deformation in the mold release step to be described later. In the curing step, as schematically shown in step 6 in FIG. 1, the curable composition (A) is heated, thereby curing the curable composition (A) and forming a cured film. The liquid film of the curable composition (A) filled between the superstrate and the substrate is thus cured and changes to a cured film. The heating temperature of the curable composition (A) in the curing step is preferably 100° C. or more and 400° C. or less.

### <Mold Release Step>

In the mold release step, as schematically shown in step 7 in FIG. 1, the superstrate is released (separated) from the cured film of the curable composition (A) formed on the substrate in the curing step. When the superstrate is released from the cured film, the cured film having a flat surface is formed on the substrate. Note that the cured film having a flat surface will sometimes be referred to as a “flat cured film” hereinafter).

As a method of releasing the superstrate from the cured film on the substrate, a method capable of preventing a part of the flat cured film from being physically broken at the time of release suffices, and various kinds of conditions and the like are not particularly limited. For example, the superstrate may be released from the cured film on the substrate by moving the superstrate away from the substrate in a state in which the substrate is fixed. Alternatively, the superstrate may be released from the cured film on the substrate by moving the superstrate away from the substrate in a state in which the superstrate is fixed. The superstrate may be released from the cured film on the substrate by moving both the superstrate and the substrate in opposite directions.

### <Hard Baking Step>

In the film forming method according to the embodiment of the present invention, for the purpose of obtaining desired film properties in the cured film formed on the substrate via the mold release step, a hard baking step of heating the cured film on the substrate again after the mold release step may be executed. For example, in a case where the curable composition (A2) is used as the curable composition (A), when the hard baking step is provided, volatilization of the remaining solvent and carbonization of the remaining curable composition can be promoted, and a flat cured film having an etching resistance can be obtained. In a case where the curable composition (A3) is used as the curable composition (A), when the hard baking step is provided, volatilization of the remaining solvent and formation of a three-dimensional crosslinking structure by dehydration condensation can be promoted, and a flat cured film having an etching resistance, a heat resistance, transparency, and insulating properties can be obtained. The upper limit of the heating temperature in the hard baking step is preferably the heat resistant temperature. When performing measurement using TGA, the heat resistant temperature can be obtained by placing the curable composition (A) after curing in a nitrogen atmosphere with a flow rate of 5 L/hrs to 6 L/hrs and measuring the thermal weight decrease rate when the temperature is increased up to n° C. at a heating speed of 20° C./min. A temperature at which the thermal weight decrease rate reaches 2% for the first time is defined as the heat resistant temperature. An example of a major apparatus is STA 1000 (manufactured by Linseis).

### [Article Manufacturing Method]

An article manufacturing method according to an embodiment of the present invention includes a forming step of forming a planarization film of a curable composition on a substrate using the above-described film forming method, a processing step of processing the substrate with the planarization film formed in the forming step, and a manufacturing step of manufacturing an article from the substrate processed in the processing step. The film forming method is a method of forming a planarization film on a substrate using a superstrate, as described above, and can include, for example, an arranging step, a waiting step, a contact step, a curing step, and a mold release step.

A well-known photolithography step such as an imprint lithography technique or an extreme ultraviolet exposure technique (EUV) can be performed on the planarization film formed on the substrate by the film forming method according to the embodiment of the present invention. It is also possible to stack a spin-on-glass (SOG) film and/or a silicon oxide layer, and perform a photolithography step by applying a curable composition on that. Consequently, a device such as a semiconductor device can be fabricated. It is further possible to form an apparatus including the device, for example, an electronic apparatus such as a display, a camera, or a medical apparatus. Examples of the device are an LSI, a system LSI, a DRAM, an SDRAM, an RDRAM, a D-RDRAM, and a NAND flash memory.

Here, an article is, for example, an electric circuit element, an optical element, MEMS, a recording element, a sensor, or a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. Examples of the optical element are a micro lens, a light guide body, a waveguide, an antireflection film, a diffraction grating, a polarizer, a color filter, a light-emitting element, a display, and a solar battery. Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprinting.

More practical examples will be explained below in order to supplement the above-described embodiments. Example 1 in which a silicon wafer is used as a superstrate and Comparative Example 1 in which a quartz wafer is used as a superstrate will be described below. Note that as a substrate, a silicon wafer is used.

### Example 1

A silicon wafer can be prepared as a superstrate that satisfies the above-described conditions of the embodiment of the present invention. Hence, in Example 1, a silicon wafer whose size is 300 mΦ and whose number of foreign substances having a size of 50 nm or more is less than 10 is used as a superstrate. The silicon wafer as a superstrate may be cleaned using a commercially available cleaning apparatus.

### Comparative Example 1

It is difficult to prepare a quartz wafer as a superstrate that satisfies the above-described conditions of the embodiment of the present invention. More specifically, it is difficult to obtain a quartz wafer whose size is 300 mΦ and whose number of foreign substances having a size of 50 nm or more is less than 100. Hence, in Comparative Example 1, a quartz wafer whose size is 300 mΦ and whose number of foreign substances having a size of 50 nm or more is 100 or more is used as a superstrate.

The thermal expansion coefficients of the silicon wafer and the quartz wafer at 290 K to 310 K are shown in a table below. In a case where a silicon wafer is used as a substrate, and a quartz wafer is used as a superstrate (Comparative Example 1), the thermal expansion coefficient of the substrate is 4×10⁻⁶ K⁻¹, and the thermal expansion coefficient of the superstrate is 6×10⁻⁷ K⁻¹ That is, in Comparative Example 1, the thermal expansion coefficient ratio of the substrate and the superstrate is six times or more. On the other hand, in a case where a silicon wafer is used as a substrate, and a silicon wafer is used as a superstrate as well (Example 1), the thermal expansion coefficients of the substrate and the superstrate are 4×10⁻⁶ K⁻¹ and are equal. Hence, in the case where a silicon wafer is used as a superstrate (Example 1), the thermal expansion coefficient difference between the substrate and the superstrate is small, as compared to the case where a quartz wafer is used as a superstrate (Comparative Example 1). That is, the strain of the cured film formed on the substrate by the film forming method according to the embodiment of the present invention can be made smaller.

TABLE 1

| Material of wafer | Silicon | Quartz |
|---|---|---|
| Size | 300 mmΦ | 300 mmΦ |
| Thermal expansion | 4 × 10⁻⁶ | 6 × 10⁻⁷ |
| coefficient at 290 K to | | |
| 310 K [K⁻¹] | | |
| Number of foreign | less than 10 | 100 or more |
| substances having size | | |
| of 50 nm or more | | |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-017429 filed on Feb. 7, 2024, which is hereby incorporated by reference herein in its entirety.

What is claimed is:

1. A film forming method of forming a planarization film on a substrate using a superstrate having a flat surface, comprising:
discretely arranging a curable composition (A) as a plurality of droplets on a substrate;
waiting until the plurality of droplets arranged on the substrate in the arranging combine with each other on the substrate to form a liquid film;
bringing the liquid film on the substrate and the flat surface of the superstrate into contact with each other after the waiting;
heating and curing the liquid film after the bringing, thereby forming a cured film between the superstrate and the substrate; and
releasing the superstrate from the cured film after the curing,
wherein the curable composition (A) arranged on the substrate in the arranging is a thermosetting curable composition having a characteristic of being cured by heating, and contains at least a solvent (d),
wherein a viscosity of the curable composition (A) at 23° C. is not less than 2 mPa·s and not more than 60 mPa·s,
wherein a content of the solvent (d) in the curable composition (A) is not less than 5 vol % and not more than 95 vol %,
wherein a boiling point of the solvent (d) at normal pressure is less than 250° C., and
wherein a mixture other than the solvent (d) in the curable composition (A) has a viscosity of not less than 30 mPa·s and not more than 10,000 mPa·s at 23° C.

2. The method according to claim 1, wherein the superstrate is a silicon wafer.

3. The method according to claim 1, wherein a thermal expansion coefficient of the superstrate at 290 K to 310 K is not less than 1×10⁻⁶ K⁻¹ and not more than 7×10⁻⁶ K⁻¹.

4. The method according to claim 1, wherein in the arranging, the curable composition (A) is discretely arranged as the plurality of droplets on the substrate using an inkjet method.

5. The method according to claim 1, wherein when a temperature is increased from 200° C. to 250° C. at a heating speed of 20° C./min, a weight decrease of the cured film obtained in the curing is not more than 2%.

6. The method according to claim 1, wherein
the curable composition (A) contains at least a polymerizable compound (a) and a radical generator (b), and
the polymerizable compound (a) contains at least a polymerizable compound (a-1) containing not less than one aromatic ring or aromatic heterocycle, and a vinyl group directly combining with the aromatic ring or aromatic heterocycle.

7. The method according to claim 6, wherein
the polymerizable compound (a) contains not less than one type of polymerizable compound, and
a boiling point of each of the not less than one type of polymerizable compound at normal pressure is not less than 250° C.

8. The method according to claim 6, wherein
the polymerizable compound (a) contains not less than one type of polymerizable compound, and
a molecular weight of each of the not less than one type of polymerizable compound is not less than 200.

9. The method according to claim 6, wherein
the polymerizable compound (a) contains not less than one type of polymerizable compound, and
a vapor pressure of each of the not less than one type of polymerizable compound at 80° C. is not more than 0.001 mmHg.

10. The method according to claim 6, wherein as the polymerizable compound (a), at least a polymer having a polymerizable functional group is contained.

11. The method according to claim 1, wherein
the curable composition (A) contains a compound (p) including a benzene ring and having a molecular weight of 300 to 5,000, a thermal acid generator (r), and a crosslinking agent(s), and
a content of carbon atoms in the mixture other than the solvent (d) in the curable composition (A) is not less than 80 wt %.

12. The method according to claim 1, wherein
the curable composition (A) contains a siloxane component (q), and
a content of silicone atoms in the mixture other than the solvent (d) in the curable composition (A) is not less than 30 wt %.

13. The method according to claim 1, wherein the curable composition (A) contains a surfactant.

14. The method according to claim 1, wherein
the solvent (d) contains not less than one type of solvent, and
a boiling point of each of the not less than one type of solvent at normal pressure is not less than 80° C. and less than 250° C.

15. The method according to claim 1, wherein
the solvent (d) contains not less than one type of solvent, and
a boiling point of each of the not less than one type of solvent at normal pressure is not less than 150° C. and less than 200° C.

16. The method according to claim 1, wherein the solvent (d) contains a polymerizable compound whose boiling point at normal pressure is not less than 80° C. and less than 250° C.

17. The method according to claim 1, wherein a content of the solvent (d) in the curable composition (A) is not less than 5 vol % and not more than 85 vol %.

18. The method according to claim 1, wherein the curable composition (A) is a curable composition for inkjet.

19. The method according to claim 1, wherein in the waiting, a process waits until a content of the solvent (d) in the liquid film becomes not more than 10 vol % with respect to the mixture.

20. The method according to claim 1, wherein in the waiting, the substrate is heated under conditions that a temperature is not less than 30° C. and not more than 200° C., and a heating time is not less than 10 sec and not more than 600 sec.

21. The method according to claim 1, further comprising heating the cured film on the substrate after the releasing.

22. An article manufacturing method comprising:
forming a planarization film on a substrate using a film forming method defined in claim 1;
processing the substrate with the planarization film formed in the forming; and
manufacturing an article from the substrate processed in the processing.
